(19) United States
(12) Patent Application Publication
(10) Pub. No.: US 2012/0224128 A1
(43) Pub. Date: Sep. 6, 2012

(54) DISPLAY APPARATUS, METHOD OF MANUFACTURING THE SAME, AND METHOD OF DRIVING THE SAME

(75) Inventors: Kwang-chul JUNG, Seongnam-si (KR); Hyeokjin LEE, Seongnam-si (KR); Ohjeong KWON, Hwaseong-si (KR)

(73) Assignee: SAMSUNG ELECTRONICS CO., LTD., Suwon-si (KR)

(21) Appl. No.: 13/276,726

(22) Filed: Oct. 19, 2011

(30) Foreign Application Priority Data
Mar. 4, 2011 (KR) 10-2011-0019555

(51) Int. Cl. G02F 1/1337; H01L 33/08; G02F 1/1333

(52) U.S. Cl. 349/129; 349/138; 438/30; 257/E33.012

(57) ABSTRACT

A display apparatus includes a first substrate including a first base substrate, a first pixel electrode disposed on the first base substrate, an insulating layer on the first pixel electrode, and a second pixel electrode disposed on the insulating layer and including a plurality of slits; a second substrate including a second base substrate opposite the first base substrate and on the first base substrate, and a reference electrode disposed on the second base substrate and facing the second pixel electrode; and a liquid crystal layer is disposed between the second pixel electrode and the reference electrode, the liquid crystal layer including liquid crystal molecules which are vertically aligned relative to the first and second substrates.

### CROSS-REFERENCE TO RELATED APPLICATION

This application claims priority to Korean Patent Application No. 10-2011-0019555, filed on Mar. 4, 2011, and all the benefits accruing therefrom under 35 U.S.C. §119, the content of which in its entirety is herein incorporated by reference.

### BACKGROUND OF THE INVENTION

1. Field of the Invention

This disclosure relates to a display apparatus capable of preventing the formation of texture defects and improving response speed, a method of manufacturing the display apparatus, and a method of driving the display apparatus.

2. Description of the Related Art

In general, a liquid crystal display includes two transparent substrates and a liquid crystal layer disposed between the two substrates. The alignment of the liquid crystal layer selected to control light transmittance of the liquid crystal layer in each pixel, thereby displaying a desired image.

A driving mode of the liquid crystal display is a vertical alignment mode. In a vertical alignment mode, liquid crystal molecules of the liquid crystal layer are vertically aligned when an electric filed is generated between the two substrates, so that light may be transmitted through the liquid crystal layer and the image displayed. In particular, in a patterned vertical alignment mode liquid crystal display, which may be obtained by patterning a pixel electrode and a common electrode of the liquid crystal display, liquid crystal domains are formed by the patterning of the pixel electrode and the common electrode. As a result, the liquid crystal molecules are aligned in different directions, and thus a viewing angle of the liquid crystal display is improved.

However, when the pixel electrode and the common electrode are patterned in order to form the liquid crystal domains, the complexity and cost of a manufacturing process is increased. In addition, if a misalignment occurs between the pixel electrode and the common electrode, the desired liquid crystal domain is not formed.

### BRIEF SUMMARY OF THE INVENTION

An exemplary embodiment provides a display apparatus capable of substantially or effectively preventing the formation of texture defects and improving response speed, and may have a structure in which a slit formed in a pixel electrode and a reference electrode is not patterned.

Another exemplary embodiment provides a method of manufacturing the display apparatus.

Yet another exemplary embodiment provides a method of driving the display apparatus.

According to an exemplary embodiment, disclosed is a display apparatus including a first substrate including a first base substrate, a first pixel electrode disposed on the first base substrate, an insulating layer disposed on the first pixel electrode, and a second pixel electrode disposed on the insulating layer and including a plurality of slits; a second substrate including a second base substrate opposite the first base substrate and on the first base substrate, and a reference electrode disposed on the second base substrate and facing the second pixel electrode; and a liquid crystal layer disposed between the second pixel electrode and the reference electrode, the liquid crystal layer including liquid crystal molecules which are vertically aligned relative to the first and second substrates.

According to an exemplary embodiment, a method of manufacturing a display apparatus is disclosed. The method includes: manufacturing a first substrate including a first base substrate, a first pixel electrode disposed on the first base substrate, an insulating layer disposed on the first pixel electrode, a second pixel electrode disposed on the insulating layer and including a plurality of slits; manufacturing a second substrate including a second base substrate opposite the first base substrate and on the first base substrate, and a reference electrode disposed on the second base substrate and facing the second pixel electrode; forming a first alignment layer on the second pixel electrode; forming a second alignment layer on the reference electrode, forming a liquid crystal layer including a light-curable agent between the second pixel electrode and the reference electrode; applying a voltage to the second pixel electrode and the reference electrode to form an electric field between the second pixel electrode and the reference electrode; and irradiating a light while the electric field is present to form a first light cured layer and a second light cured layer on the first alignment layer and the second alignment layer, respectively, to manufacture the display apparatus.

According to another exemplary embodiment, disclosed is a method of manufacturing a display apparatus. The method includes manufacturing a first substrate including a first base substrate, a first pixel electrode disposed on the first base substrate, an insulating layer disposed on the first pixel electrode, a second pixel electrode disposed on the insulating layer and including a plurality of slits; manufacturing a second substrate including a second base substrate opposite the first base substrate and on the first base substrate, and a reference electrode disposed on the second base substrate and facing the second pixel electrode; forming a first alignment layer including a light-curable agent on the second pixel electrode; forming a second alignment layer including the light-curable agent on the reference electrode; forming a liquid crystal layer between the first alignment layer and the second alignment layer; applying a voltage to the second pixel electrode and the reference electrode to form an electric field between the second pixel electrode and the reference electrode; and irradiating a light while the electric field is present to form a first light cured layer and a second light cured layer on the first alignment layer and the second alignment layer, respectively, to manufacture the display apparatus.

According to another exemplary embodiment, disclosed is a method of driving a display apparatus. The method includes: applying a reset voltage to a third sub-pixel electrode and a fourth sub-pixel electrode in response to an (i−1)th gate signal, wherein i is a natural number equal to or larger than 2; applying a data voltage to a first sub-pixel electrode and a second sub-pixel electrode in response to an i-th gate signal; and lowering the data voltage applied to the second sub-pixel electrode to drive the display apparatus.

According to the above, the first sub-pixel electrode, which is driven in an image display mode, and the second sub-pixel electrode, which is used in an electric field exposure process, are disposed on the first substrate, and the second pixel electrode includes the slits.

Thus, the display apparatus may substantially or effectively prevent the response speed from being delayed in the image display mode by the electric field and the formation of texture defects in the electric field exposure process.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a block diagram of an embodiment of a liquid crystal display;

FIG. 2 is a perspective view of an embodiment of a pixel of a plurality of pixels shown in FIG. 1;

FIG. 3 is a flowchart showing an embodiment of a method of manufacturing a super vertical alignment (“SVA”) mode liquid crystal display panel;

FIG. 4 is a cross-sectional view showing an embodiment of forming of an electric field of the method shown in FIG. 3;

FIG. 5 is a cross-sectional view showing an embodiment of forming of a light-cured layer of the method shown in FIG. 3;

FIG. 6 is a flowchart showing an embodiment of a method of manufacturing a surface-stabilized vertical alignment (“SS-VA”) mode liquid crystal display panel;

FIG. 7 is a cross-sectional view showing an embodiment of forming of an electric field of the method shown in FIG. 6;

FIG. 8 is a cross-sectional view showing an embodiment of forming of a light-cured layer of the method shown in FIG. 3;

FIG. 9 is an equivalent circuit diagram of an embodiment of a pixel;

FIG. 10A is a plan view showing a layout of the pixel shown in FIG. 9;

FIG. 10B is an enlarged view of a portion I shown in FIG. 10A;

FIG. 11 is a graph of time (milliseconds, ms) versus voltage (V) showing electric potentials at the first to fourth nodes shown in FIG. 9;

FIG. 12 is an equivalent circuit diagram of an embodiment of a pixel;

FIG. 13A is a plan view showing a layout of the pixel shown in FIG. 12;

FIG. 13B is an enlarged view of a portion II shown in FIG. 13A; and

FIG. 14 is a graph of time (milliseconds, ms) versus voltage (V) showing electric potentials at the first to fourth nodes shown in FIG. 12.

### DETAILED DESCRIPTION OF THE INVENTION

It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers, and/or sections, these elements, components, regions, layers and/or sections should not be limited by these terms. These terms are only used to distinguish one element, component, region, layer, or section from another region, layer, or section. Thus, a first element, component, region, layer, or section discussed below could be termed a second element, component, region, layer, or section without departing from the teachings of the present invention.

Spatially relative terms, such as “beneath”, “below”, “lower”, “above”, “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a,” “an,” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

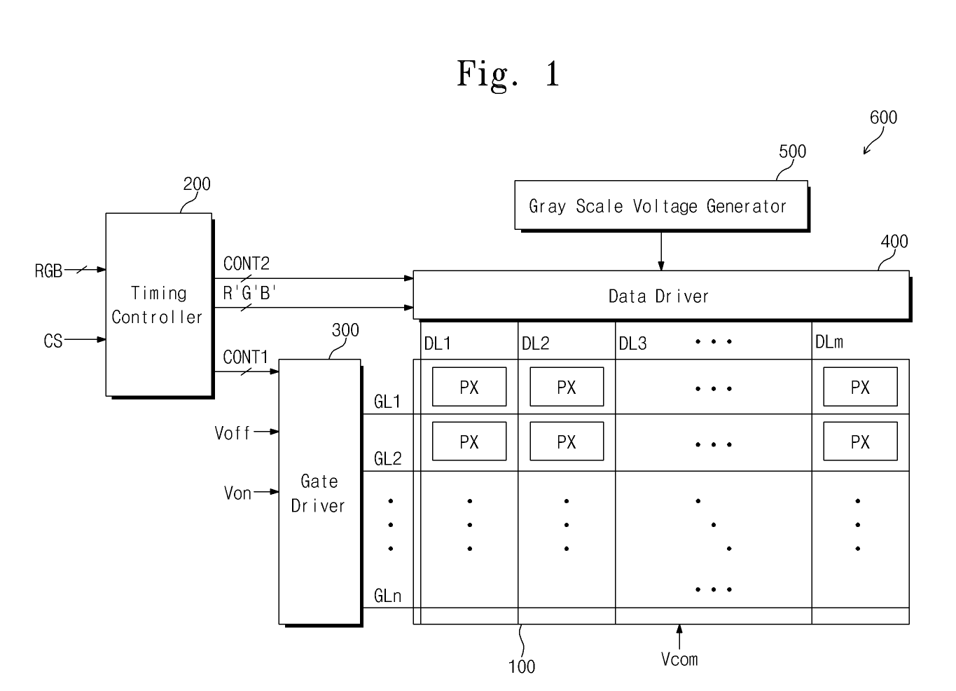

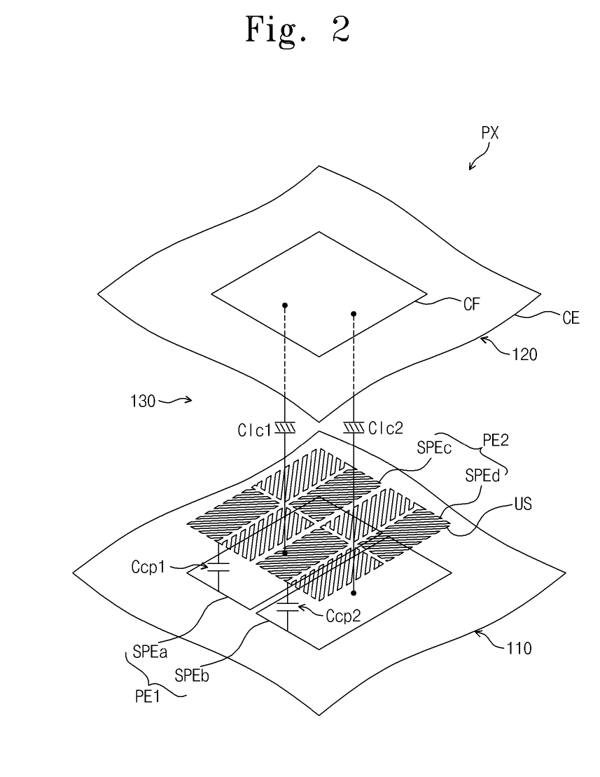

FIG. 1 is a block diagram showing an embodiment of a liquid crystal display and FIG. 2 is a perspective view showing an embodiment of a pixel of a plurality of pixels shown in FIG. 1. Referring to FIG. 1, a liquid crystal display 600 includes a liquid crystal display panel 100, a timing controller 200, a gate driver 300, a data driver 400, and a gray scale voltage generator 500.

The liquid crystal display panel 100 is connected to a plurality of signal lines and includes a plurality of pixels PX, which are arranged in a matrix. As shown in FIG. 2, the liquid crystal display panel 100 may include a first substrate 110, a second substrate 120 opposite the first substrate 110, and a liquid crystal layer 130 interposed between the first and second substrates 110 and 120.

The signal lines include a plurality of gate lines GL1 to GLn receiving a gate signal and a plurality of data lines DL1 to DLm receiving a data voltage. The gate lines GL1 to GLn extend in a row direction and are arranged in parallel to each other, and the data lines DL1 to DLm extend in a column direction and are arranged in parallel to each other.

The pixels PX each have the same structure and function, and thus one pixel will be described with reference to FIG. 2 as a representative example.

As shown in FIG. 2, each pixel PX includes a first sub-pixel and a second sub-pixel. The first sub-pixel includes a first coupling capacitor Ccp1 and a first liquid crystal capacitor Clc1, and a second sub-pixel includes a second coupling capacitor Ccp2 and a second liquid crystal capacitor Clc2.

The first substrate 110 includes a first sub-pixel electrode SPEa as a first electrode of the first coupling capacitor Ccp1 and a second sub-pixel electrode SPEb as a first electrode of the second coupling capacitor Ccp2. In addition, the first substrate 110 includes a third sub-pixel electrode SPEc as a first electrode of the first liquid crystal capacitor Clc1 and a fourth sub-pixel electrode SPEd as a first electrode of the second liquid crystal capacitor Clc2. The third and fourth sub-pixel electrodes SPEc and SPEd respectively face (e.g., are disposed opposite) the first and second sub-pixel electrodes SPEa and SPEb and may serve as second electrodes of the first and second coupling capacitor Ccp1 and Ccp2, respectively. An insulating layer (not shown) is interposed between the first and third sub-pixel electrodes SPEa and SPEc and between the second and fourth sub-pixel electrodes SPEb and SPEd and serves as a dielectric layer.

The second substrate 120 includes a reference electrode CE, which may be a second electrode of each of the first and second liquid crystal capacitor Clc1 and Clc2. The liquid crystal layer 130 is interposed between the first substrate 110 and the second substrate 120 and may serve as a dielectric layer of each of the first and second liquid crystal capacitors Clcl and Clc2.

The first and second sub-pixel electrodes SPEa and SPEb are electrically insulated from each other and form a first pixel electrode PE1. The third and fourth sub-pixel electrodes SPEc and SPEd are electrically insulated from each other and form a second pixel electrode PE2. In addition, a plurality of fine slits US is disposed (e.g., formed) in the third and fourth sub-pixel electrodes SPEc and SPEd.

The reference electrode CE is disposed (e.g., formed) on the second substrate 120 and may receive a reference voltage Vcom. The liquid crystal layer 130 has a negative anisotropic dielectric constant, and liquid crystal molecules in the liquid crystal layer 130 may be vertically aligned with respect to a surface of the first and second substrates 110 and 120 when no electric field is applied.

In addition, in an embodiment the liquid crystal display 600 may display a desired color using a spatial division method in which each pixel PX represents a primary color (i.e., red, green, or blue) or a time division method (i.e., temporal division) in which each pixel PX represents the primary colors in turn according to the time lapse. FIG. 2 shows an example of the spatial division method, and accordingly a color filter CF representing one of the primary colors is provided in the embodiment of FIG. 2 on the second substrate 120 to correspond to each pixel. Different from the above-mentioned structure shown in FIG. 2, the color filter CF may be disposed on or under the first and second sub-pixel electrodes SPEa and SPEb of the first substrate 110.

Referring to FIG. 1 again, the timing controller 200 receives a plurality of image signals RGB and a plurality of control signals CS from the outside of the liquid crystal display 600. The timing controller 200 converts a data format of the image signals RGB into a data format appropriate for an interface between the data driver 400 and the timing controller 200 and applies the converted image signals R′G′B′ to the data driver 400. In addition, the timing controller 200 applies data control signals CONT2, such as an output start signal, a horizontal start signal, etc., to the data driver 400 and applies gate control signals CONT1, such as a vertical start signal, a clock signal, a clock bar signal, etc., to the gate driver 300.

The gray scale voltage generator 500 generates all gray scale voltages related to the transmittance of the pixels PX, or a limited number of the gray scale voltages (hereinafter, referred to as a reference gray scale voltage). The reference gray scale voltage may have a positive or negative value with respect to the reference voltage Vcom.

The gate driver 300 generates the gate signal including a gate on voltage Von and a gate off voltage Voff in response to the gate control signals CONT1 provided from the timing controller 200. The gate signal is sequentially applied to the gate lines GL1 to GLn of the liquid crystal display panel 100.

The data driver 400 is operated in response to the data control signals CONT2 provided from the timing controller 200 and converts the image signals R′G′B′ into data voltages based on the reference gray scale voltage. The data voltages are applied to the data lines DL1 to DLm of the liquid crystal display panel 100.

Each of the timing controller 200, the gate driver 300, the data driver 400, and the gray scale voltage generator 500 may be directly mounted on the liquid crystal display panel 100 in the form of an integrated circuit (“IC”) chip, attached to the liquid crystal display panel 100 in the form of a tape carrier package (“TCP”) after being mounted on a flexible printed circuit film (not shown), or mounted on a separate printed circuit board (not shown). In addition, at least one of the timing controller 200, the gate driver 300, the data driver 400, and the gray scale voltage generator 500 may be integrated in the liquid crystal display panel 100 through a thin film process. Further, the timing controller 200, the gate driver 300, the data driver 400, and the gray scale voltage generator 500 may be integrated in a single chip.

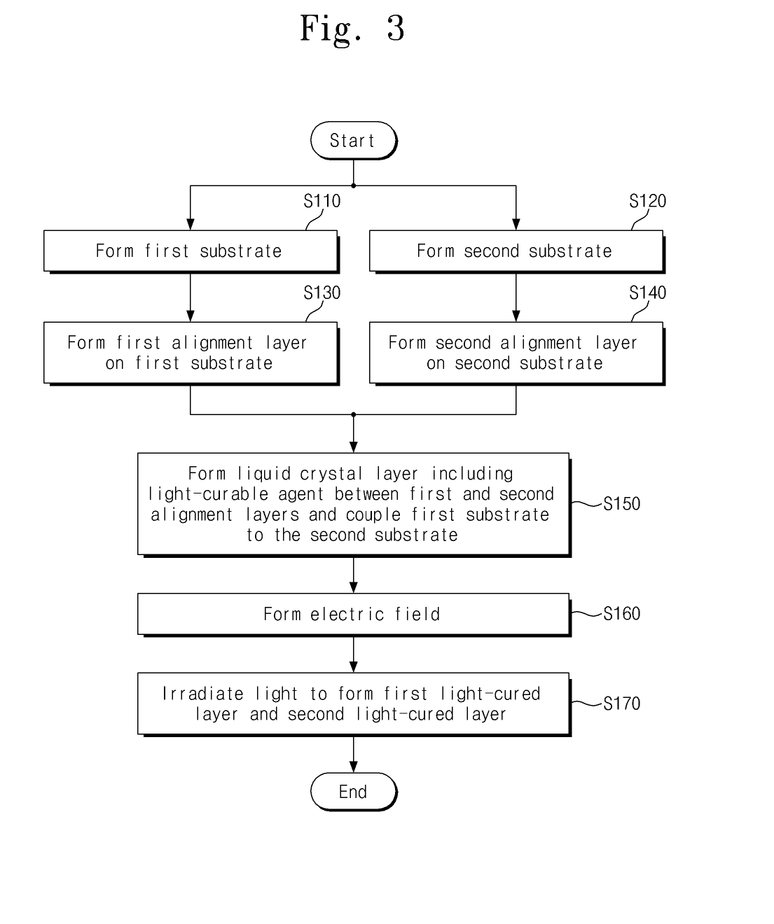

Hereinafter, a method of manufacturing a super vertical alignment (“SVA”) mode liquid crystal display panel 100 will be further disclosed with reference to FIGS. 3 to 5.

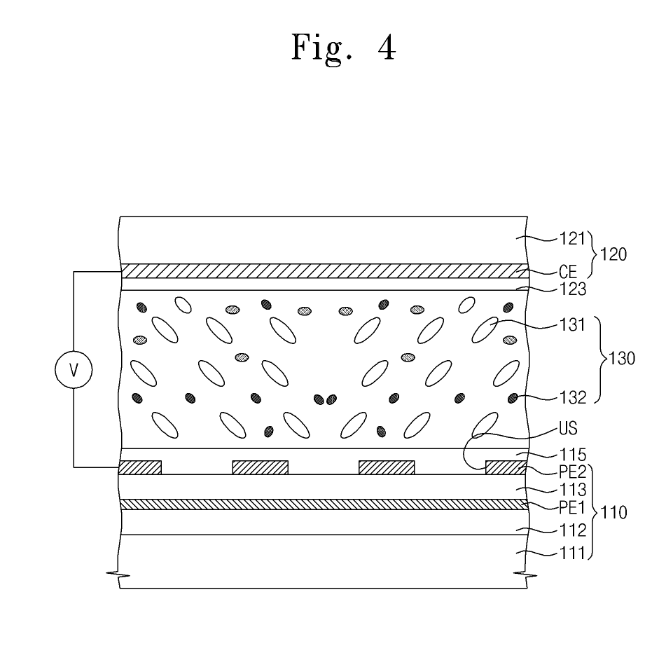

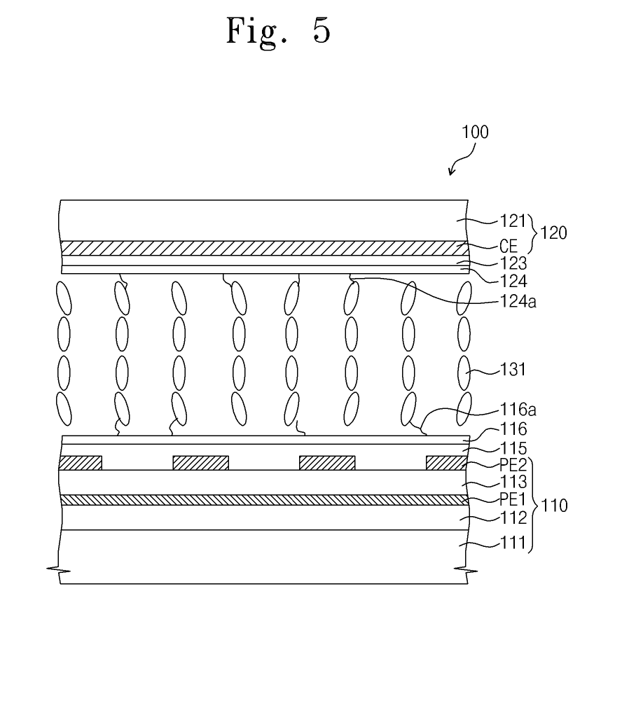

FIG. 3 is a flowchart showing an embodiment of a method of manufacturing an SVA mode liquid crystal display panel, FIG. 4 is a cross-sectional view showing an embodiment of forming of an electric field shown in FIG. 3, and FIG. 5 is a cross-sectional view showing an embodiment of forming of a light-cured layer shown in FIG. 3.

Referring to FIG. 3, the first substrate 110 and the second substrate 120 of the liquid crystal display panel 100 are formed in processes S110 and S120.

As show in FIG. 4, the first substrate 110 includes a first base substrate 111, a first pixel electrode PE1 disposed on the first base substrate 111, and a second pixel electrode PE2 provided with a plurality of fine slits US. The first substrate 110 further includes a first insulating layer 112 disposed between the first base substrate 111 and the first pixel electrode PE1 and a second insulating layer 113 disposed between the first pixel electrode PE1 and the second pixel electrode PE2 to electrically insulate the first and second pixel electrodes PE1 and PE2 from each other.

The second substrate 120 includes a second base substrate 121 disposed on (e.g., coupled to) the first base substrate 111 and opposite the first base substrate 111, and a reference electrode CE disposed on the second base substrate 121 and facing the second pixel electrode PE2.

When the first and second substrates 110 and 120 are formed, a first alignment layer 115 and a second alignment layer 123 are formed on the first substrate 110 and the second substrate 120, respectively, in processes S130 and S140. The first alignment layer 115 is disposed on the second pixel electrode PE2 and the second insulating layer 113, and the second alignment layer 123 is disposed on the reference electrode CE.

The first and second alignment layers 115 and 123 may be respectively coated on the first and second substrates 110 and 120 using an ink-jet method or a roll printing method. In addition, the first and second alignment layers 115 and 123 may be the same as those applied to a vertical alignment mode liquid crystal display or a twisted nematic mode liquid crystal display.

Then, the liquid crystal layer 130 including a light-curable agent 132 is disposed (e.g., formed) between the first and second alignment layers 115 and 123, respectively. The first substrate 110 is disposed on (e.g., coupled to) the second substrate 120 while interposing the liquid crystal layer 130 between the first and second substrates 110 and 120, as shown in process S150. Alternatively, in another exemplary embodiment, the liquid crystal layer 130 may be formed between the first and second alignment layers 115 and 123 after the first substrate 110 is coupled to the second substrate 120.

As shown in FIG. 4, the liquid crystal layer 130 includes a combination of liquid crystal molecules 131 and the light-curable agent 132. The light-curable agent 132 is present in an amount of not more than about 1.0 weight percent, specifically about 0.01 to about 0.9 weight percent, more specifically about 0.1 to about 0.8 weight percent, based on the total weight of the liquid crystal layer 130.

According to the present exemplary embodiment, the light-curable agent 132 may be a reactive mesogen (“RM”). The term of “mesogen” means a light bridge low-molecular weight polymer or a high-molecular weight copolymer including a mesogen group having a liquid crystal properties. Examples of suitable reactive mesogens are those including acrylate, methacrylate, epoxy, oxetane, vinyl-ether, styrene, and thiol-ene groups. Representative examples of the reactive liquid crystal material include the reactive mesogens C3M, RMM34, and RM, each available from Merck KGaA, and LC242 available from BASF. In addition, the reactive mesogen may have a structure having cylindrical or bar shape, a curved cylindrical bar or banana shape, a planar or board shape, or a disc shape.

Although not shown in figures, the liquid crystal layer 130 may further include a radical initiator. The radical initiator may be present in an amount of about 0.01 weight percent to about 1 weight percent, specifically about 0.05 to about 0.9 weight percent, more specifically about 0.1 to about 0.8 weight percent, based on the total weight of the light-curable agent 132. The radical initiator may absorb long-wave ultraviolet light and may provide a radical to initiate or facilitate an optical polymerization reaction. The radical initiator may be an azo compound, such as azobisisobutyronitrile, or 1,1′-azobis(cyclohexanecarbonitrile), or an organic peroxide, such as di-tert-butyl peroxide or benzoyl peroxide.

After the coupling of the first and second substrates 110 and 120, the first and second substrates 110 and 120 may be annealed at a temperature of about 100 degrees Celsius to about 120 degrees Celsius, specifically about 105 degrees Celsius to about 115 degrees Celsius, more specifically about 110 degrees Celsius in a chamber for a time of about 60 minutes to about 80 minutes, specifically about 65 minutes to about 75 minutes.

When a voltage is applied to the second pixel electrode PE2 of the first substrate 110 and the reference electrode CE of the second substrate 120 after the coupling of the first and second substrates 110 and 120, the electric field is generated between the first and second substrates 110 and 120 in process S160.

The second pixel electrode PE2 is applied with a selected exposure voltage and the reference electrode CE is applied with a ground voltage or a voltage of about zero volts. The exposure voltage and the ground voltage may be respectively applied to the second pixel electrode PE2 and the reference electrode CE for a time of about 1 to about 300 seconds, specifically about 10 to about 250 seconds, more specifically about 20 to about 200 seconds. In addition, the exposure voltage may be about 5 volts to about 20 volts, specifically about 6 volts to about 18 volts, more specifically about 7 volts to about 16 volts.

When the electric field is generated, the liquid crystal molecules 131 included in the liquid crystal layer 130 are aligned.

Then, the light (i.e., the ultraviolet light) is irradiated onto the liquid crystal layer 130 while the electric field is generated (e.g., present) to perform an electric field exposure. The light may be irradiated onto the liquid crystal layer 130 from one or both sides of the first and second substrates 110 and 120.

When the light is irradiated onto the liquid crystal layer 130 while the electric field is generated, the liquid crystal molecules 131 adjacent to the first and second alignment layers 115 and 123 are tilted almost parallel to a longitudinal direction of the fine slits US. In addition, the light-curable agent 132, which is in the liquid crystal layer, is cured by the light irradiating on the liquid crystal layer 130 to have the same tilt angle as the liquid crystal molecules 131 on the first and second alignment layers 115 and 123.

Accordingly, a first light-cured layer 116 and a second light-cured layer 124 are formed on the first alignment layer 115 and the second alignment layer 123, respectively, as shown in FIG. 5, in process S170.

When the electric field is not generated (e.g., is not present), the side chain of polymers 116a and 124a of the first and second light-cured layers 116 and 124 maintain the alignment direction of the adjacent liquid crystal molecules 131. As further disclosed above, the polymers of the first and second light-cured layers 116 and 124 may maintain a pretilt of the liquid crystal molecules 131 with respect to the longitudinal direction of the fine slits US. As a result, the liquid crystal molecules 131 are inclined more rapidly when the electric field is generated to drive the liquid crystal display panel 100, thereby improving the response speed of the liquid crystal display 600.

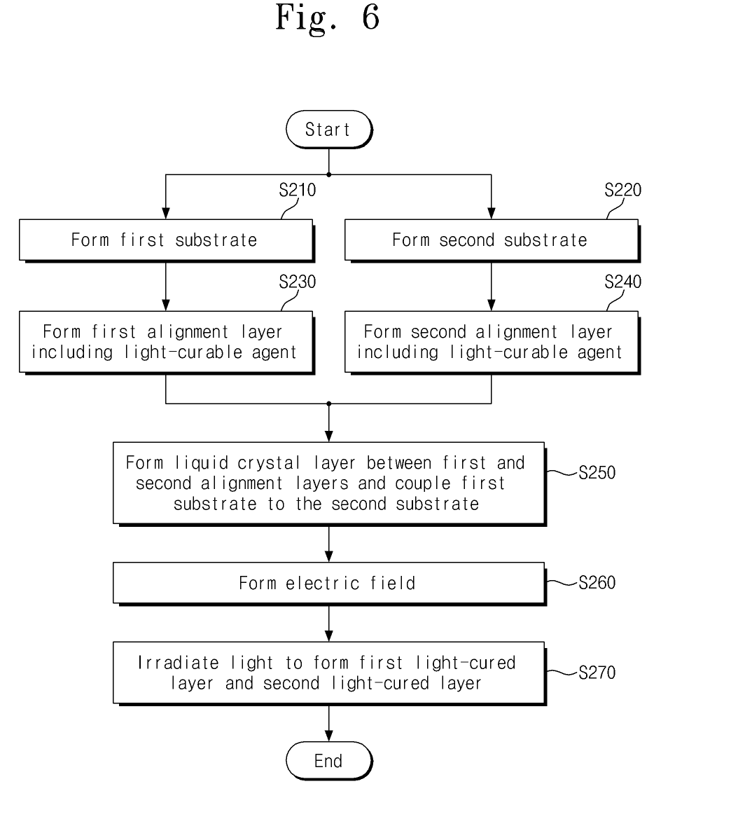

Hereinafter, a method of manufacturing a surface-stabilized vertical alignment mode liquid crystal display panel 100 will be further disclosed with reference to FIGS. 6 to 8.

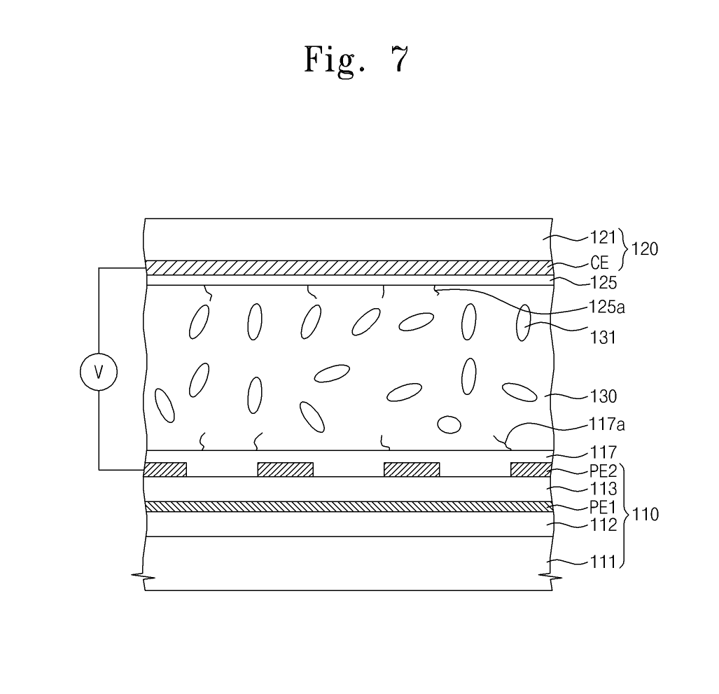

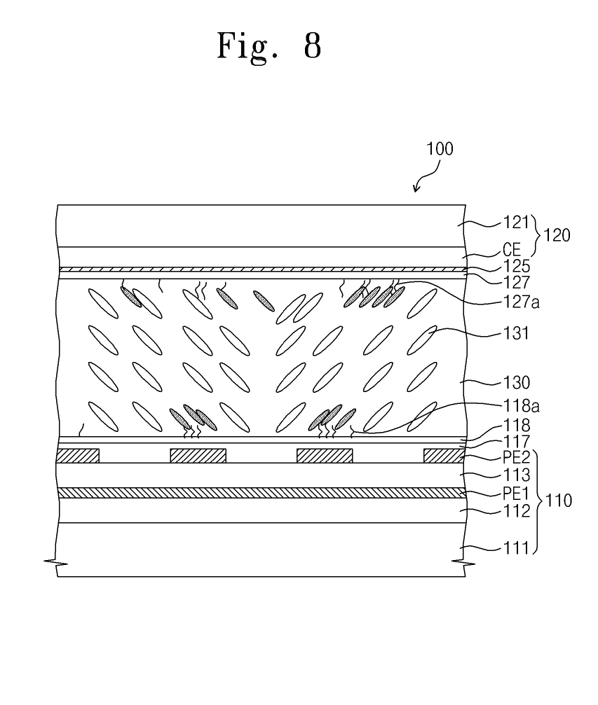

FIG. 6 is a flowchart showing an embodiment of method of manufacturing an SS-VA mode liquid crystal display panel, FIG. 7 is a cross-sectional view showing an embodiment of forming of an electric field shown in FIG. 6, and FIG. 8 is a cross-sectional view showing an embodiment of forming of a light-cured layer shown in FIG. 3.

Referring to FIG. 6, the first substrate 110 and the second substrate 120 of the liquid crystal display panel 100 are formed in processes S210 and S220. The processes of forming the first and second substrates 110 and 120 are substantially the same as those shown in FIGS. 3 and 4, and thus details thereof are not repeated.

When the first and second substrate 110 and 120 are formed, a first alignment layer 117 including a surface curing agent is formed on the first substrate 110 and a second alignment layer 125 including a surface curing agent is formed on the second substrate 120 in processes S230 and S240. The first alignment layer 117 is disposed on the second pixel electrode PE2 and the second insulating layer 113, and the second alignment layer 125 is disposed on the reference electrode CE.

The first and second alignment layers 115 and 123 may be respectively formed on the first and second substrates 110 and 120 by coating a composition containing a combination or a compound of a surface alignment agent and the surface curing agent on the first and second substrates 110 and 120 using an ink-jet method or a roll printing method. The surface alignment agent is used as a vertical alignment material so as to align the liquid crystal molecules 131 to be vertical with respect to the surface of the second pixel electrode PE2 and the reference electrode CE.

The surface alignment agent may be present in an amount ranging from about 85 mol percent to about 95 mol percent, specifically about 85 mol percent to about 95 mol percent, more specifically about 85 mol percent to about 95 mol percent, based on 100 mol percent of the reactant, and the surface curing agent may be present in an amount ranging from about 5 mol percent to about 15 mol percent. In addition, as an example, the surface curing agent may be the reactive mesogen (RM).

Then, the liquid crystal layer 130 is formed between the first and second alignment layers 117 and 125. The first substrate 110 is coupled to the second substrate 120 while interposing the liquid crystal layer 130 between the first and second substrates 110 and 120 in process S250.

When a voltage is applied to the second pixel electrode PE2 of the first substrate 110 and the reference electrode CE of the second substrate 120 after the coupling of the first and second substrates 110 and 120, the electric field is generated between the first and second substrates 110 and 120 in process S260.

The second pixel electrode PE2 is applied with a selected exposure voltage and the reference electrode CE is applied with a ground voltage or a voltage of about zero volts.

Then, the light (i.e., the ultraviolet light) is irradiated onto the liquid crystal layer 130 while the electric field is generated to perform the electric field exposure. When the electric field is generated, the surface curing agent is aligned in the same direction as the liquid crystal molecules 131. When the light is irradiated onto the liquid crystal layer 130 after the surface curing agent is aligned in the same direction as the liquid crystal molecules 131, the surface curing agent is cured. Thus, a first light-cured layer 118 and a second light-cured layer 127 are formed on the first and second alignment layers 117 and 125 by the surface curing agent, respectively, and the liquid crystal molecules 131 adjacent to the first and second light cured layers 118 and 127 have a selected pretilt angle.

The surface curing agent 117a shown in FIG. 7 is a polymer in which vertically-aligned molecules of a surface alignment material are chemically bonded to molecules including reactive mesogen (“RM”). The reactive mesogen included in the surface curing agent 117a and 125a further forms the side chains 118a and 127a. As a result, the first and second light-cured layers 118 and 127 may be formed, as shown in FIG. 6, process S270.

Since the first and second light-cured layers 118 and 127 are cured to allow the side chains 118a and 127a to be arranged along the pretilt angle of the liquid crystal molecules 131, when the electric field is not generated between the first and second substrates 110 and 120, the liquid crystal molecules 131 may maintain the pretilt angle in the direction substantially parallel to the longitudinal direction of the fine slits US, even though the electric field is not present between the first and second substrates 110 and 120. As a result, the liquid crystal molecules 131 are inclined rapidly when the electric field is generated to drive the liquid crystal display panel 100, thereby improving the response speed of the liquid crystal display 600.

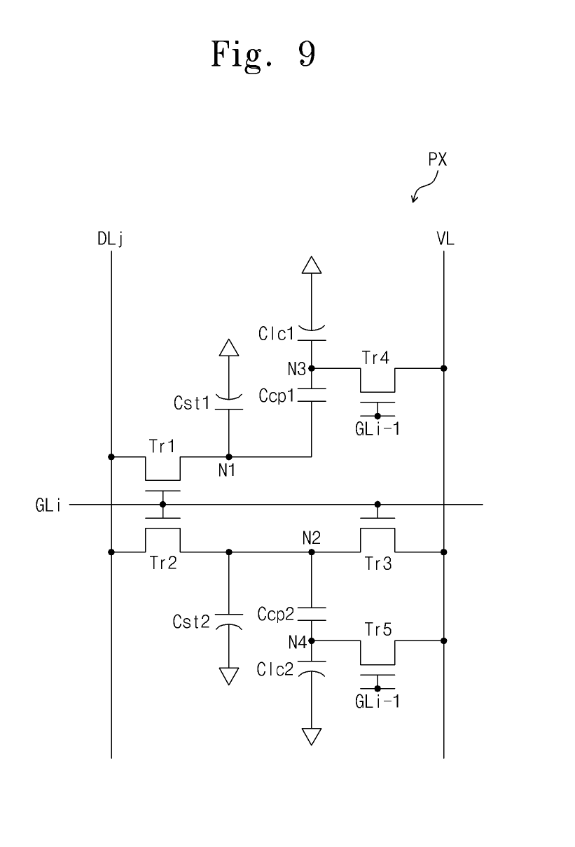

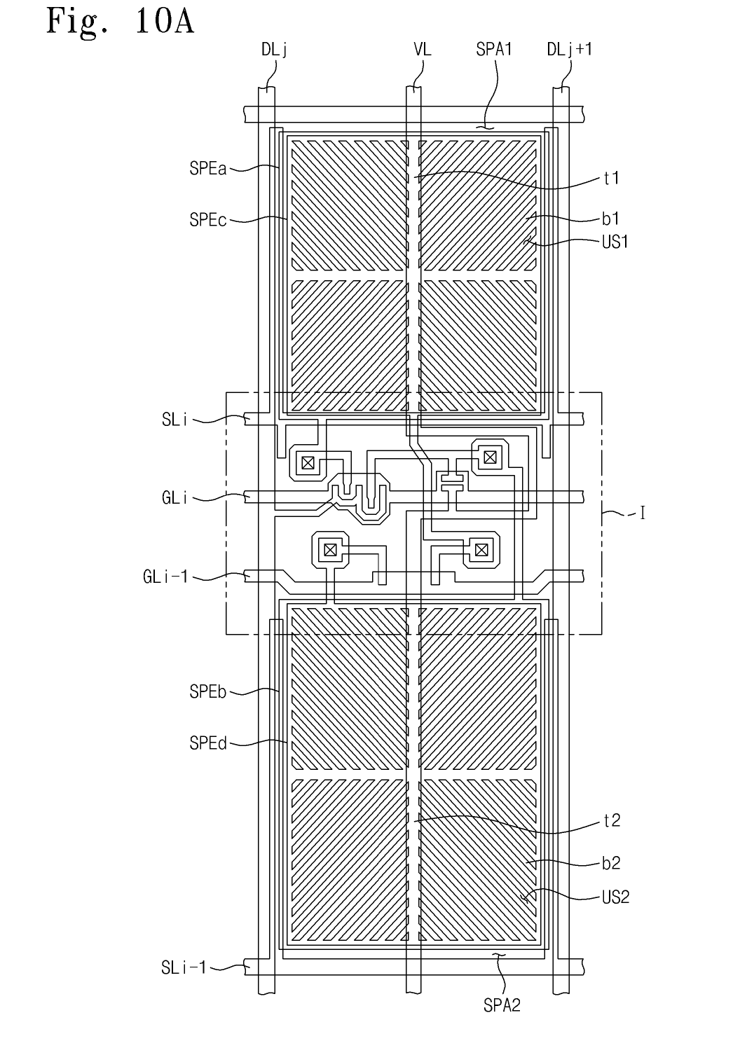

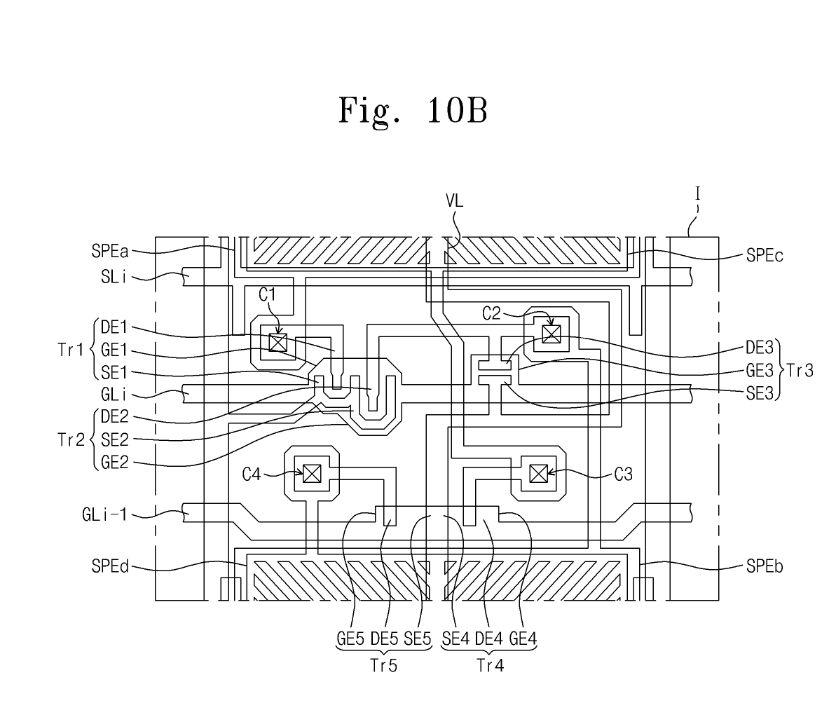

FIG. 9 is an equivalent circuit diagram of an embodiment of a pixel, FIG. 10A is a plan view showing a layout of the pixel shown in FIG. 9, and FIG. 10B is an enlarged view of a portion I shown in FIG. 10A. The equivalent circuit diagram shown in FIG. 9 is driven under a voltage-division scheme.

Referring to FIGS. 9, 10A, and 10B, the equivalent circuit diagram of the pixel PX includes a first gate line GLi, a data line DLj, a first storage line SLi, a second storage line SLi−1, a second gate line GLi−1, and a voltage line VL.

In addition, the pixel PX includes a first thin film transistor Tr1, a second thin film transistor Tr2, a third thin film transistor Tr3, first and second liquid crystal capacitors Clc1 and Clc2, first and second storage capacitors Cst1 and Cst2, and first and second coupling capacitors Ccp1 and Ccp2.

The first thin film transistor Tr1 includes a gate electrode GE1 electrically connected to the first gate line GLi, a source electrode SE1 electrically connected to the data line DLj, and a drain electrode DE1 electrically connected to the first coupling capacitor Ccp1. The second thin film transistor Tr2 includes a gate electrode GE2 electrically connected to the first gate line GLi, a source electrode SE2 electrically connected to the data line DLj, and a drain electrode DE2 electrically connected to the second coupling capacitor Ccp2.

The pixel PX includes the first sub-pixel electrode SPEa as the first electrode of the first coupling capacitor Ccp1 and the second sub-pixel electrode SPEb as the first electrode of the second coupling capacitor Ccp2. The first sub-pixel electrode SPEa is electrically connected to the drain electrode DE1 of the first thin film transistor Tr1 through a first contact hole C1, and the second sub-pixel electrode SPEb is electrically connected to the drain electrode DE2 of the second thin film transistor Tr2 through the second contact hole C2.

The pixel PX further includes the third sub-pixel electrode SPEc as the second electrode of the first coupling capacitor Ccp1 and the fourth sub-pixel electrode SPEd as the second electrode of the second coupling capacitor Ccp2.

Although not shown in FIGS. 9, 10A, and 10B, the third and fourth sub-pixel electrodes SPEc and SPEd face the reference electrode CE of the second substrate 120 and liquid crystal layer is interposed between the reference electrode CE and the third and fourth sub-pixel electrodes SPEc and SPEd, thereby forming the first and second liquid crystal capacitors Clc1 and Clc2.

In addition, the first and second sub-pixel electrodes SPEa and SPEb partially overlap the first and second storage lines SLi and SLi−1, respectively, while at least one insulating layer is interposed therebetween, to thereby form the first and second storage capacitors Cst1 and Cst2.

The third thin film transistor Tr3 includes a gate electrode GE3 connected to the first gate line GLi, a source electrode SE3 connected to the voltage line VL, and a drain electrode DE3 connected to the drain electrode DE2 of the second thin film transistor Tr2. As an example, an electric potential at a second node N2 may vary depending on a ratio of a channel length between the second and third thin film transistors Tr2 and Tr3. Accordingly, the electric potential at the second node N2 may be set to the desired level by selecting the ratio of the channel length between the second and third thin film transistors Tr2 and Tr3.

For instance, when the data voltage of about 10 volts is applied to the data line DLj after the first to third thin film transistors Tr1, Tr2, and tr3 are turned on in response to a first gate signal Gi applied to the first gate line GLi, the electric potential at a first node N1 is raised to about 10 volts by the first thin film transistor Tr1. In addition, when the ratio of the channel length between the second and third thin film transistors Tr2 and Tr3 is set to 8:2, the electric potential at the second node N2 is set to about 8 volts by dividing the data voltage of about 10 volts.

Thus, in the case of a one-gate line-one data line (1G-1D) structure in which the first and second sub-pixels share the first gate line GLi and the data line DLj, the first and second sub-pixels may be charged with different voltages than each other.

In addition, the pixel PX may further include a fourth thin film transistor Tr4 and a fifth thin film transistor Tr5.

The fourth thin film transistor Tr4 includes a gate electrode GE4 electrically connected to the second gate line GLi−1, a source electrode SE4 electrically connected to the voltage line VL, and a drain electrode DE4 electrically connected to the third sub-pixel electrode SPEc. The fifth thin film transistor Tr5 includes a gate electrode GE5 electrically connected to the second gate line GLi−1, a source electrode SE5 electrically connected to the voltage line VL, and a drain electrode DE5 electrically connected to the fourth sub-pixel electrode SPEd. The drain electrode DE4 of the thin film transistor Tr4 is electrically connected to the third sub-pixel electrode SPEc through a third contact hole C3, and the drain electrode DE5 of the fifth thin film transistor Tr5 is electrically connected to the fourth sub-pixel electrode SPEd through a fourth contact hole C4.

The voltage line VL receives a reset voltage from an external source and the second gate line GLi−1 receives a second gate signal Gi−1. The second gate signal Gi−1 may be generated prior to the first gate signal Gi by at least one horizontal scanning period 1H.

When the fourth and fifth thin film transistors Tr4 and Tr5 are turned on in response to the second gate signal Gi−1, the reset voltage may be applied to a third node N3 and a fourth node N4. Accordingly, the electric potential at the third and fourth nodes N3 and N4 may be reset to the reset voltage before the first gate signal Gi is generated. As is further disclosed above, when the first gate signal is applied after the electric potential at the third and fourth nodes N3 and N4 are reset to the reset voltage, the electric potential at the first and second nodes N1 and N2 may be stably controlled.

Referring to FIG. 10A, the third sub-pixel electrode SPEc includes a first main portion t1 (hereinafter, referred to as a first trunk portion) and a plurality of first sub-portions b1 (hereinafter, referred to as first branch portions) extending from the first trunk portion t1 in a radial manner in order to divide a first sub-pixel area SPA1 into a plurality of domains. The first trunk portion t1 has a cross shape, so that the first sub-pixel area SPA1 may be divided into four domains by the first trunk portion t1. The first branch portions b1 extend parallel to each other in each domain and are spaced apart from each other. As an example, the first branch portions b1 may extend in a direction at about 45 degrees with respect to the first trunk portion t1. In the first branch portions b1, each branch of the first branch portions b1 is spaced apart from an adjacent branch of the first branch portion thereto by a distance of about several micrometers, specifically about 1 to about 20 millimeters, more specifically about 2 to about 10 millimeters, thereby forming a plurality of first fine slits US1. The liquid crystal molecules in the liquid crystal layer 130 are tilted in different directions in each domain by the first fine slits US1.

The fourth sub-pixel electrode SPEd includes a second main portion t2 (hereinafter, referred to as a second trunk portion), and a plurality of second sub-portions b2 (hereinafter, referred to as second branch portions), which extend from the second trunk portion t2 in a radial manner in order to divide a second sub-pixel area SPA2 into a plurality of domains. The second trunk portion t2 has the cross shape, so that the second sub-pixel area SPA2 may be divided into four domains by the second trunk portion t2. The second branch portions b2 extend parallel to each other in each domain and are spaced apart from each other. In the second branch portions b2, each branch of the second branch portions b2 is spaced apart from an adjacent branch of the second branch portion thereto by a distance of about several micrometers, specifically about 1 to about 20 millimeters, more specifically about 2 to about 10 millimeters, to thereby form a plurality of second fine slits US2. The liquid crystal molecules in the liquid crystal layer 130 are tilted in different directions in each domain by the second fine slits US2.

As an example, the voltage line VL extends parallel to the data line DLj. In addition, the voltage line VL is disposed between the data line DLj and an adjacent data line DLj+1 and is partially overlapped with the first and second trunk portions t1 and t2. In further detail, the voltage line VL may be overlapped with portions of the first and second trunk portions t1 and t2, which are parallel to the data line DLj.

Since the first and second trunk portions t1 and t2 divide the domains in the first and second sub-pixel areas SPA1 and SPA2, areas in which the first and second trunk portions t1 and t2 are disposed correspond to non-effective display areas. When the voltage line VL is disposed (e.g., formed) to overlap with the first and second trunk portions t1 and t2, an aperture ratio and a transmittance of each pixel PX may be substantially or effectively prevented from being deteriorated by the voltage line VL.

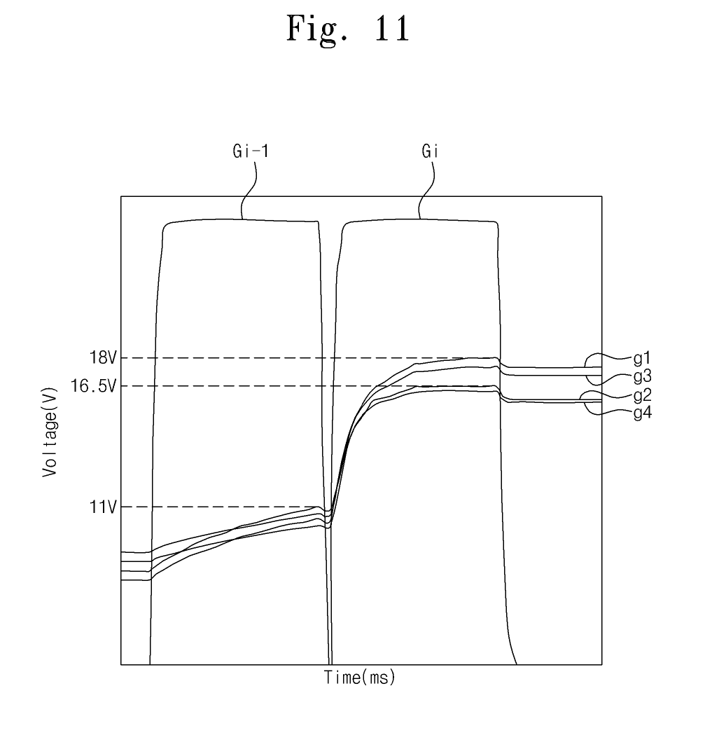

FIG. 11 is a graph showing electric potentials at the first to fourth nodes shown in FIG. 9. In FIG. 11, first, second, third, and fourth curves g1, g2, g3, and g4 respectively represent electric potentials at the first, second, third, and fourth nodes N1, N2, N3, and N4 when the data voltage of about 18 volts is applied to the data line DLj.

Referring to FIGS. 9 and 11, when the fourth and fifth thin film transistors Tr4 and Tr5 are turned on in response to the second gate signal Gi−1, the reset voltage (i.e., about 11 volts) may be applied to the third node N3 and the fourth node N4. Accordingly, the electric potential at the third and fourth nodes N3 and N4 may be reset to the reset voltage before the first gate signal Gi is generated.

Then, when the first to third thin film transistors Tr1, Tr2, and Tr3 are turned on in response to the first gate signal Gi, the electric potential at the first node N1 is increased to the data voltage (i.e., about 18 volts). However, the electric potential at the second node N2 is made to the voltage of about 16.5 volts by the voltage division between the second and third transistors Tr2 and Tr3.

According to the increase of the electric potential of the first and second nodes N1 and N2, the electric potentials at the third and fourth nodes N3 and N4 are each gradually increased from the reset voltage. The electric potentials at the third and fourth nodes N3 and N4 have a value smaller than the electric potential at the first and second nodes N1 and N2 according to the capacitance of the first and second coupling capacitors Ccp1 and Ccp2. In addition, the electric potential difference between the first and third nodes N1 and N3 and the electric potential difference between the second and fourth nodes N2 and N4 may be controlled by selecting the thickness of the insulating layer disposed between the first and second pixel electrodes PE1 and PE2.

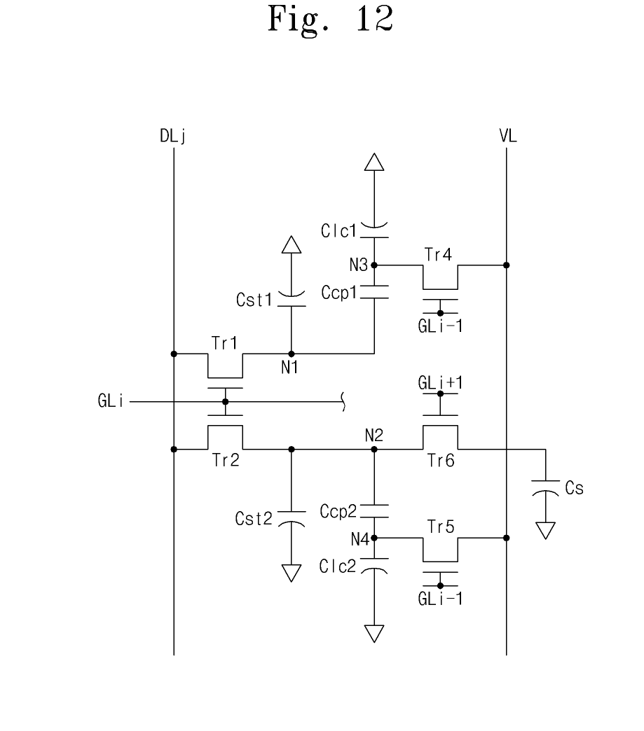

Hereinafter, a pixel operated under a charge sharing scheme will be disclosed with reference to FIGS. 12 to 14.

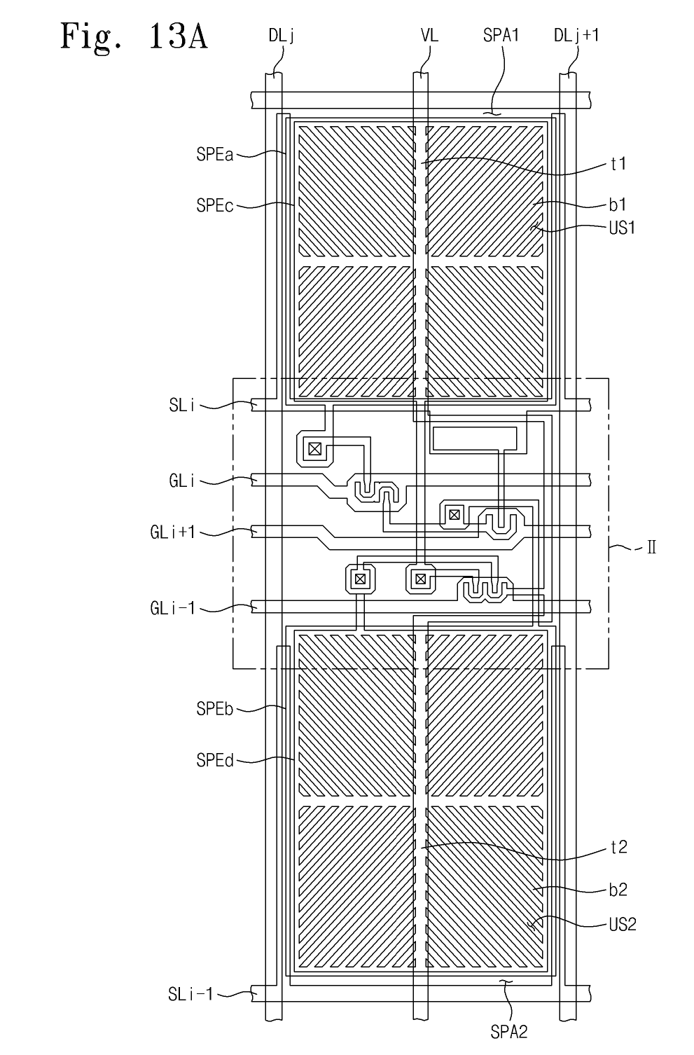

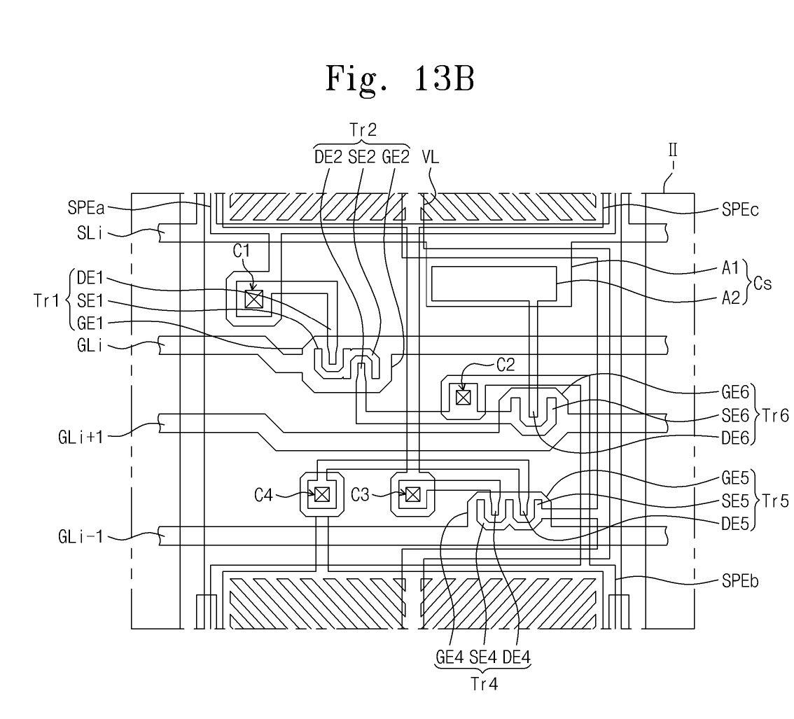

FIG. 12 is an equivalent circuit diagram of a pixel according to another exemplary embodiment of the present invention, FIG. 13A is a plan view showing a layout of the pixel shown in FIG. 12, and FIG. 13B is a partially enlarged view of a portion II shown in FIG. 13A. In FIGS. 12, 13A, and 13B, the same reference numerals denote the same elements in FIGS. 9, 10A, and 10B, and thus detailed descriptions of the same elements are not repeated.

Referring to FIGS. 12, 13A, and 13B, the equivalent circuit diagram of the pixel PX includes a first gate line GLi, a data line DLj, first and second storage lines SLi and SLi−1, a second gate line GLi−1, a third gate line GLi+1, and a voltage line VL.

In addition, the pixel PX has the same structure and function as those of the pixel PX shown in FIG. 9 except for a sixth thin film transistor Tr6 and a charge-sharing capacitor Cs instead of the third thin film transistor Tr3 shown in FIG. 9.

The sixth thin film transistor Tr6 includes a gate electrode GE6 electrically connected to the third gate line GLi+1, a source electrode SE6 electrically connected to a drain electrode DE2 of the second thin film transistor Tr2, and a drain electrode DE6 electrically connected to the charge-sharing capacitor Cs. The charge-sharing capacitor Cs includes a first electrode A1 branched from the first storage line SLi and a second electrode A2 branched from the drain electrode DE6 of the sixth thin film transistor Tr6. An insulating layer (not shown) may be interposed between the first and second electrodes A1 and A2, and the insulating layer may serve as a dielectric layer of the charge-sharing capacitor Cs.

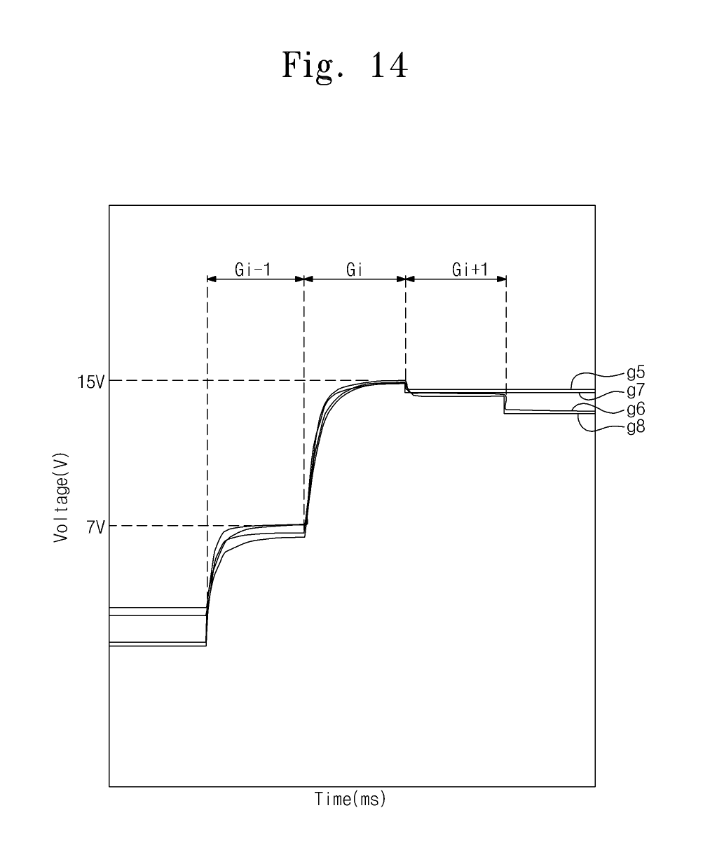

FIG. 14 is a graph showing electric potentials at first to fourth nodes shown in FIG. 12. In FIG. 14, fifth, sixth, seventh, and eighth curves g5, g6, g7, and g8 respectively represent electric potentials at the first, second, third, and fourth nodes N1, N2, N3, and N4 when the data voltage of about 15 volts is applied to the data line DLj.

Referring to FIGS. 12 and 14, when the fourth and fifth thin film transistors Tr4 and Tr5 are turned on in response to the second gate signal Gi−1, the reset voltage (i.e., about 7 volts) may be applied to the third node N3 and the fourth node N4. Accordingly, the electric potential at the third and fourth nodes N3 and N4 may be reset to the reset voltage (about 7 volts) before the first gate signal Gi is generated.

Then, when the first and second thin film transistors Tr1 and Tr2 are turned on in response to the first gate signal Gi, the electric potential at the first and second nodes N1 and N2 is increased to the data voltage (i.e., about 15 volts). That is, the electric potential at the first node N1 becomes substantially the same as the electric potential at the second node N2. According to the increase of the electric potential at the first and second nodes N1 and N2, the electric potentials at the third and fourth nodes N3 and N4 are gradually increased from the reset voltage.

When the sixth thin film transistor Tr6 is turned on in response to the third gate signal Gi+1, the charge-sharing capacitor Cs is electrically connected to the second coupling capacitor Ccp2. Thus, the charge-sharing capacitor Cs, the second coupling capacitor Ccp2, and the second liquid crystal capacitor Clc2 may share the charge.

Accordingly, the electric potential at the second node N2 is lowered by the charge-sharing during the turned-on period of the sixth thin film transistor Tr6. Therefore, although the sixth thin film transistor Tr6 is turned off, the electric potential at the second node N2 maintains the lowered state.

When the second liquid crystal capacitor Clc2 and the charge-sharing capacitor Cs share the charge by using the sixth thin film transistor Tr6, the data voltage charged in the second liquid crystal capacitor Clc2 is lowered. Consequently, a voltage occurs between the data voltage charged in the first liquid crystal capacitor Clc1 and the data voltage charged in the second liquid crystal capacitor Clc2. That is, the data voltage charged in the first liquid crystal capacitor Clc1 has a level larger than that of the data voltage charged in the second liquid crystal capacitor C1c2.

As is further disclosed above, the data voltages charged in the first and second liquid crystal capacitors Clc1 and C1c2 formed in one pixel PX have different values from each other, thereby improving side visibility. In further detail, when the data voltages corresponding to two gamma curves having different gamma values obtained from one image information are stored in the first and second liquid crystal capacitors Clc1 and C1c2, respectively, the gamma curve of the pixel including the first and second liquid crystal capacitors Clc1 and C1c2 becomes the composite gamma curve of the two gamma curves. The composite gamma curve approaches a reference gamma curve, when the composite gamma curve is measured from in front of the display and when measured from the side of the display. Thus, the side visibility, e.g., viewing angle, may be improved.

Accordingly, the side visibility of the liquid crystal display 600 may be improved. Although the exemplary embodiments of the present invention have been described, it is understood that the present invention should not be limited to these exemplary embodiments but various changes and modifications can be made by one ordinary skilled in the art within the spirit and scope of the hereinafter claims.

What is claimed is:

1. A display apparatus comprising:
a first substrate comprising
a first base substrate,
a first pixel electrode disposed on the first base substrate,
an insulating layer disposed on the first pixel electrode, and
a second pixel electrode disposed on the insulating layer and comprising a plurality of slits;
a second substrate comprising
a second base substrate opposite the first base substrate and on the first base substrate, and
a reference electrode disposed on the second base substrate and facing the second pixel electrode; and
a liquid crystal layer disposed between the second pixel electrode and the reference electrode, the liquid crystal layer comprising liquid crystal molecules which are vertically aligned relative to the first and second substrates.

2. The display apparatus of claim 1, wherein
the first pixel electrode comprises a first sub-pixel electrode and a second sub-pixel electrode which is electrically insulated from the first sub-pixel electrode, and
the second pixel electrode comprises a third sub-pixel electrode facing the first sub-pixel electrode and a fourth sub-pixel electrode facing the second sub-pixel electrode, wherein the insulating layer is between the first sub-pixel electrode and the third sub-pixel electrode, and is between the second sub-pixel electrode and the fourth sub-pixel electrode.

3. The display apparatus of claim 2, further comprising:
a first gate line disposed on the first base substrate;
a data line insulated from the first gate line and crossing the first gate line;
a first thin film transistor electrically connected to the first gate line, the data line, and the first sub-pixel electrode; and
a second thin film transistor electrically connected to the first gate line, the data line, and the second sub-pixel electrode.

4. The display apparatus of claim 3, further comprising:
a voltage line which receives a reset voltage; and
a third thin film transistor electrically connected to the first gate line, the voltage line, and the second sub-pixel electrode.

5. The display apparatus of claim 4, further comprising:
a second gate line disposed on the first base substrate and electrically insulated from the first gate line;
a fourth thin film transistor electrically connected to the second gate line, the voltage line, and the third sub-pixel electrode; and
a fifth thin film transistor electrically connected to the second gate line, the voltage line, and the fourth sub-pixel electrode.

6. The display apparatus of claim 5, wherein the third sub-pixel electrode comprises a first trunk portion which defines a plurality of first domains and a plurality of second branch portions which extend from the first trunk portion and are parallel to each other in each of the first domains, and the fourth sub-pixel electrode comprises a second trunk portion which defines a plurality of second domains and a plurality of second branch portions which extend from the second trunk portion and are parallel to each other in each of the second domains.

7. The display apparatus of claim 6, wherein the voltage line is substantially parallel to the data line and partially overlaps the first and second trunk portions.

8. The display apparatus of claim 5, further comprising:
a third gate line disposed on the first base substrate and electrically insulated from the first and second gate lines;
a charge-sharing capacitor; and
a sixth thin film transistor electrically connected to the third gate line, the second sub-pixel electrode, and the charge-sharing capacitor.

9. The display apparatus of claim 1, further comprising:
a first alignment layer disposed on the first substrate, and
a second alignment layer disposed on the second substrate and facing the first alignment layer,
wherein the liquid crystal layer is between the first and second alignment layers.

10. The display apparatus of claim 9, further comprising:
a first light-cured layer disposed on the first alignment layer which pretilts the liquid crystal molecules adjacent to the second pixel electrode; and
a second light-cured layer disposed on the second alignment layer which pretilts the liquid crystal molecules adjacent to the reference electrode.

11. A method of manufacturing a display apparatus, the method comprising:
manufacturing a first substrate including
a first base substrate,
a first pixel electrode disposed on the first base substrate,
an insulating layer disposed on the first pixel electrode, and
a second pixel electrode disposed on the insulating layer and comprising a plurality of slits;
manufacturing a second substrate including
a second base substrate opposite the first base substrate and on the first base substrate, and
a reference electrode disposed on the second base substrate and facing the second pixel electrode;
forming a first alignment layer on the second pixel electrode;
forming a second alignment layer on the reference electrode;
forming a liquid crystal layer comprising a light-curable agent between the second pixel electrode and the reference electrode;
applying a voltage to the second pixel electrode and the reference electrode to form an electric field between the second pixel electrode and the reference electrode; and
irradiating a light while the electric field is present to form a first light cured layer and a second light cured layer on the first alignment layer and the second alignment layer, respectively, to manufacture the display apparatus.

12. The method of claim 11, wherein the light-curable agent comprises a reactive mesogen.

13. A method of manufacturing a display apparatus, the method comprising:
manufacturing a first substrate including
a first base substrate,
a first pixel electrode disposed on the first base substrate,
an insulating layer disposed on the first pixel electrode,
a second pixel electrode disposed on the insulating layer and comprising a plurality of slits;
manufacturing a second substrate including
a second base substrate opposite the first base substrate and on the first base substrate, and
a reference electrode disposed on the second base substrate and facing the second pixel electrode;
forming a first alignment layer including a light-curable agent on the second pixel electrode;
forming a second alignment layer including the light-curable agent on the reference electrode;
forming a liquid crystal layer between the first alignment layer and the second alignment layer;
applying a voltage to the second pixel electrode and the reference electrode to form an electric field between the second pixel electrode and the reference electrode; and
irradiating a light while the electric field is present to form a first light cured layer and a second light cured layer on the first alignment layer and the second alignment layer, respectively, to manufacture the display apparatus.

14. The method of claim 13, wherein the light-curable agent comprises a reactive mesogen.

15. A method of driving a display apparatus, the method comprising:
applying a reset voltage to a third sub-pixel electrode and a fourth sub-pixel electrode in response to an (i−1)th gate signal, wherein i is a natural number equal to or larger than 2;
applying a data voltage to a first sub-pixel electrode and a second sub-pixel electrode in response to an i-th gate signal; and
lowering the data voltage applied to the second sub-pixel electrode to drive the display apparatus.

16. The method of claim 15, wherein the lowering of the data voltage applied to the second sub-pixel electrode is achieved by lowering an electric potential of the second sub-pixel electrode by a voltage-division scheme in response to the i-th gate signal.

17. The method of claim 15, wherein the lowering of the data voltage applied to the second sub-pixel electrode is achieved by lowering an electric potential of the second sub-pixel electrode by a charge sharing scheme in response to the (i−1)th gate signal.
